(19) United States
(12) Patent Application Publication
(10) Pub. No.: US 2011/0103162 A1
(43) Pub. Date: May 5, 2011

(54) SEMICONDUCTOR MEMORY APPARATUS

(75) Inventor: Heat Bit PARK, Ichon-si (KR)

(73) Assignee: Hynix Semiconductor Inc., Ichon-si (KR)

(21) Appl. No.: 12/650,882

(22) Filed: Dec. 31, 2009

(30) Foreign Application Priority Data
Oct. 30, 2009 (KR) 10-2009-0104386

(51) Int. Cl. G11C 7/00; G11C 8/00

(52) U.S. Cl. 365/194; 365/230.03; 365/198

(57) ABSTRACT

A semiconductor memory apparatus is provided. The semiconductor memory apparatus includes: a plurality of memory banks disposed at a predetermined distance from each other in a first direction; a common column selection control unit disposed at an outside region of the plurality of memory banks in the first direction, and configured to commonly control access to column areas of the plurality of memory banks; and a common column selection signal transmission line configured to transfer a column selection signal for controlling data access to the corresponding memory cells of the plurality of memory banks. The common column selection control unit generates the column selection signal, and a delay length of the column selection signal is adjusted based on a length of a transmission path of the column selection signal.

### CROSS-REFERENCE TO RELATED APPLICATION

The present application claims priority under 35 U.S.C. §119(a) to Korean Application No. 10-2009-0104386, filed on Oct. 30, 2009, in the Korean Intellectual Property Office, which is incorporated herein by reference in its entirety as if set forth in full.

### BACKGROUND

1. Technical Field

Various embodiments of the present disclosure generally relate to a semiconductor memory apparatus, and more particularly, to a technology which controls the skew of a column selection signal.

2. Related Art

A semiconductor memory apparatus has an internal memory area divided into a plurality of memory banks. Each of the plurality of memory banks is selectively enabled by a bank address signal. The structure of how to arrange a plurality of memory banks and internal circuits is usually determined based on operational performance and space efficiency.

FIG. 1 illustrates an internal structure of a typical semiconductor memory apparatus.

Referring to FIG. 1, a typical semiconductor memory apparatus 1 includes first memory banks BANK0_0 and BANK0_1 110 and 120, second memory banks BANK1_0 and BANK1_1 210 and 220, first to fourth column selection control units 111, 121, 211 and 221, first to fourth data write units 112, 122, 212 and 222, and first to fourth data read units 113, 123, 213 and 223.

For reference, the first memory banks BANK0_0 and BANK0_1 110 and 120 are divided into a first sub bank 110 and a second sub bank 120, and the second memory banks BANK1_0 and BANK1_1 210 and 220 are divided into a third sub bank 210 and a fourth sub bank 220. The memory banks which are each selectively enabled by a bank address signal may be arranged to be physically divided into a plurality of sub banks.

Circuits configured to control access to row areas of the memory banks are provided in row control areas X LOGIC 311 and 312, and drivers and repeaters for various internal signals are provided in a cross area XY CROSS 320.

The first data write unit 112 is configured to transfer write data to the first sub bank 110, and the first data read unit 113 is configured to sense and amplify read data transferred from the first sub bank 110. The second data write unit 122 is configured to transfer write data to the second sub bank 120, and the second data read unit 123 is configured to sense and amplify read data transferred from the second sub bank 120. The third data write unit 212 is configured to transfer write data to the third sub bank 210, and the third data read unit 213 is configured to sense and amplify read data transferred from the third sub bank 210. The fourth data write unit 222 is configured to transfer write data to the fourth sub bank 220, and the fourth data read unit 223 is configured to sense and amplify read data transferred from the fourth sub bank 220.

Meanwhile, each of the first to fourth column selection control units 111, 121, 211 and 221 is configured to control access to each column area of the first memory banks BANK0_0 and BANK0_1 110 and 120 and the second memory banks BANK1_0 and BANK1_1 210 and 220, respectively. The basic operations of the first to fourth column selection control units 111, 121, 211 and 221 are identical to one another. Therefore, the internal operation of the first column selection control unit 111 and the related internal circuits thereof will be described in detail as a representative example.

Column selection signals YI<0> to YI<i> generated by the first column selection control unit 111 control data access to the corresponding memory cell in the first sub bank 110 of the first memory banks. The column selection signals YI<0> to YI<i> may be transferred through transmission lines to the first sub bank 110. For example, when a specific column selection signal YI<k> is activated, data access to the corresponding memory cell is performed. In the data read mode, the first data read unit 113 senses and amplifies read data which is transferred from the corresponding memory cell. In the data write mode, the first data write unit 112 transfers write data to the corresponding memory cell.

As described above, the typical semiconductor memory apparatus 1 includes the column selection control units provided in each memory bank. In the above example, the column selection control unit is provided in each sub bank of the memory bank. Such a structure needs a large chip area when the column selection control units are arranged. Therefore, there is a need for technology which solves the above-described problems, without degrading the performance of the access to the column area.

### SUMMARY

Accordingly, there is a need for an improved semiconductor memory apparatus that may overcome one or more of the problems discussed above.

To attain the advantages and in accordance with the purposes of the invention, as embodied and broadly described herein, in one aspect of the present invention, a semiconductor memory apparatus includes: a plurality of memory banks disposed at a predetermined distance from each other in a first direction; a common column selection control unit disposed at an outside region of the plurality of memory banks in the first direction, and configured to commonly control access to column areas of the plurality memory banks; and a common column selection signal transmission line configured to transfer a column selection signal for controlling data access to corresponding memory cells of the plurality of memory banks. The common column selection control unit generates the column selection signal, and a delay length of the column selection signal is adjusted based on a length of a transmission path of the column selection signal.

In another aspect of the present invention, a semiconductor memory apparatus includes: first and second memory banks disposed at a predetermined distance in a first direction; a common column selection control unit disposed at an outside region of the first and second memory banks in the first direction, and configured to commonly control access to column areas of the first and second memory banks; a common column selection signal transmission line configured to transfer a column selection signal for controlling data access to corresponding memory cells of the first and second memory banks, the column selection signal being generated by the common column selection control unit; and a column selection signal repeater inserted in the common column selection signal transmission line, and configured to transfer the corresponding column selection signal for controlling data access to the memory cell in the first memory bank. A transmission path of the column selection signal for controlling data access to the memory cell in the first memory bank is longer than that of the column selection signal for controlling data access to the memory cell in the second memory bank. Furthermore, when generating the column selection signal for controlling data access to the memory cell in the second memory bank, the common column selection control unit delays the column selection signal based on a delay length of the column selection signal repeater.

Additional objects and advantages of the invention will be set forth in part in the description which follows, and in part will be obvious from the description, or may be learned by practice of the invention. The objects and advantages of the invention will be realized and attained by means of the elements and combinations particularly pointed out in the appended claims.

It is to be understood that both the foregoing general description and the following detailed description are exemplary and explanatory only and are not restrictive of the invention, as claimed.

### BRIEF DESCRIPTION OF THE DRAWINGS

The accompanying drawings, which are incorporated in and to constitute a part of this specification, illustrate various embodiments consistent with the invention and, together with the description, serve to explain the principles of the invention.

FIG. 1 illustrates an internal structure of a typical semiconductor memory apparatus.

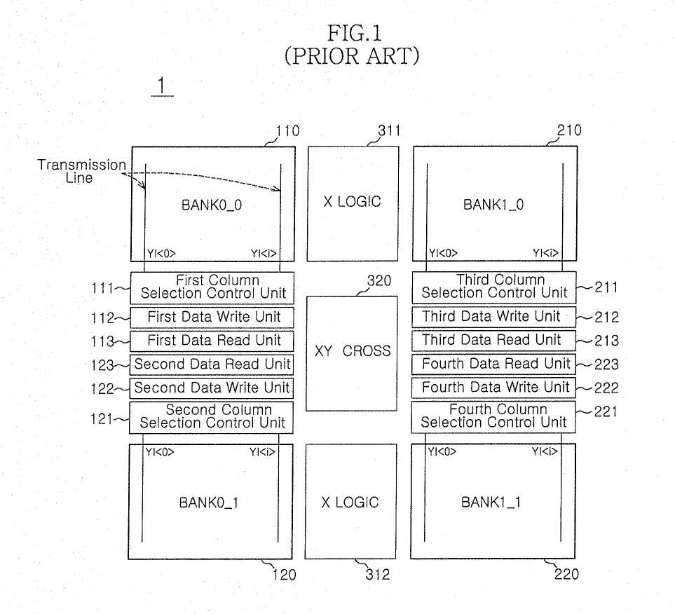

FIG. 2 illustrates an internal structure of a semiconductor memory apparatus according to a first embodiment.

FIG. 3 is a detailed configuration diagram of the semiconductor memory apparatus illustrated in FIG. 2.

FIG. 4 is a simplified diagram of the semiconductor memory apparatus of FIG. 2 and a circuit diagram of a first common column selection control unit.

FIG. 5 illustrates an internal structure of a semiconductor memory apparatus according to a second embodiment.

FIG. 6 illustrates a simulation result of the semiconductor memory apparatus according to the embodiments.

### DETAILED DESCRIPTION

Reference will now be made in detail to the exemplary embodiments consistent with the present disclosure, examples of which are illustrated in the accompanying drawings. Wherever possible, the same reference characters will be used throughout the drawings to refer to the same or like parts.

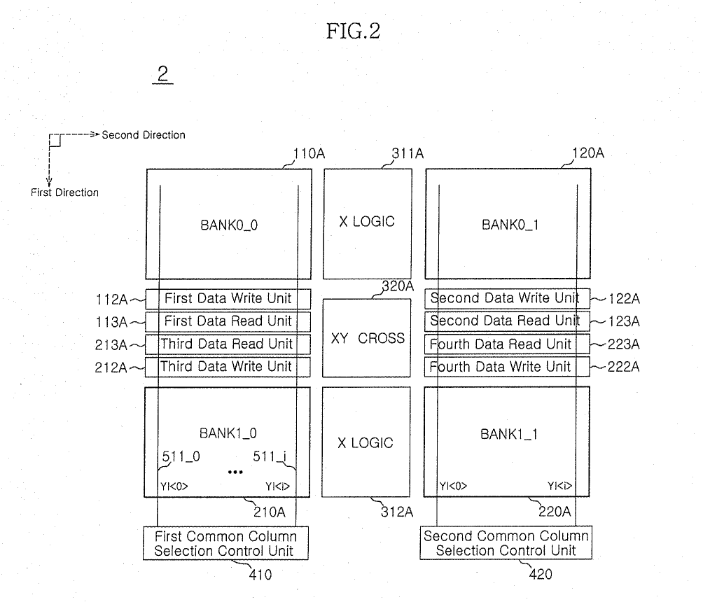

FIG. 2 illustrates an internal structure of a semiconductor memory apparatus according to a first embodiment.

The semiconductor memory apparatus 2 according to this embodiment includes only components for illustrating the proposed technical ideas. Those skilled in the art will readily understand that the semiconductor memory apparatus 2 may include other components as well.

Referring to FIG. 2, the semiconductor memory apparatus 2 includes first memory banks BANK0_0 and BANK0_1 110A and 120A, second memory banks BANK1_0 and BANK1_1 210A and 220A, first and second common column selection control units 410 and 420, first to fourth data write units 112A, 122A, 212A, and 222A, and first to fourth data read units 113A, 123A, 213A, and 223A.

For reference, the first memory banks BANK0_0 and BANK0_1 110A and 120A are divided into first and second sub banks 110A and 120A, and the second memory banks BANK1_0 and BANK1_1 210A and 220A are divided into third and fourth sub banks 210A and 220A. As such, the memory banks which are each selectively activated by a bank address signal may be arranged so as to be physically divided into the plurality of sub banks.

Now, the detailed configuration and the main operation of the semiconductor memory apparatus configured in the above-described manner will be described as follows.

The first memory banks BANK0_0 and BANK0_1 110A and 120A and the second memory banks BANK1_0 and BANK1_1 210A and 220A are disposed at a predetermined distance from each other respectively in a first direction.

Circuits configured to control access to row areas of the memory banks are provided in row control areas X LOGIC 311A and 312A, and drivers and repeaters for various internal signals are provided in a cross area XY CROSS 320A. The first row control area 311A is disposed between the first sub bank 110A and the second sub bank 120A in a second direction, and the second row control area 312A is disposed between the third sub bank 210A and the fourth sub bank 220A in the second direction. The cross area XY CROSS 320A is disposed between the first row control area 311A and the second row control area 312A in the first direction. The first and second directions are perpendicular to each other.

The first data write unit 112A is configured to transfer write data to the first sub bank 110A, and the first data read unit 113A is configured to sense and amplify read data transferred from the first sub bank 110A. The second data write unit 122A is configured to transfer write data to the second sub bank 120A, and the second data read unit 123A is configured to sense and amplify read data transferred from the second sub bank 120A. The third data write unit 212A is configured to transfer write data to the third sub bank 210A, and the third data read unit 213A is configured to sense and amplify read data transferred from the third sub bank 210A. The fourth data write unit 222A is configured to transfer write data to the fourth sub bank 220A, and the fourth data read unit 223A is configured to sense and amplify read data transferred from the fourth sub bank 220A.

The first common column selection control unit 410 is configured to control access to column areas of the first sub bank 110A of the first memory banks and the third sub bank 210A of the second memory banks. The second common column selection control unit 420 may be configured to control access to column areas of the second sub bank 120A of the first memory banks and the fourth sub is bank 220A of the second memory banks. For example, the first and second common column selection control unit 410 and 420 commonly control the first and second memory banks. The basic operations of the first and second common column selection units 410 and 420 are identical to each other. Therefore, the internal operation of the first common column selection unit 410 and the related internal circuits thereof will be described in detail as a representative example.

Column selection signals YI<0> to YI<i> generated by the first common column selection control unit 410 control data access to the corresponding memory cell in the first sub bank 110A of the first memory banks and the third sub bank 210A of the second memory banks. The column selection signals YI<0> to YI<i> are transferred to the first sub bank 110A and the third sub bank 210A through common column selection signal transmission lines 511_0 to 511_{—}i. As described above, each of the plurality of memory banks are selectively activated by a bank address signal. Therefore, although a specific column selection signal YI<k> is commonly transferred to the first sub bank 110A of the first memory banks and the third sub bank 210A of the second memory banks through the common column selection signal transmission lines 511_0 to 511_{—}i, the semiconductor memory apparatus can perform a normal operation.

When the first sub bank 110A of the first memory banks and the specific column selection signal YI<k> are activated, data access to the corresponding memory cell in the first sub bank 110A is performed. Therefore, in the data read mode, the first data read unit 113A senses and amplifies read data transferred from the corresponding memory cell. In the data write mode, the first data write unit 112A transfers write data to the corresponding memory cell. For reference, the column selection signal is activated in response to a column address signal.

When the third sub bank 210A of the second memory banks and the specific column selection signal YI<k> are activated, data access to the corresponding memory cell in the third sub bank 210A is performed. Therefore, in the data read mode, the third data read unit 213A senses and amplifies read data transferred from the corresponding memory cell. In the data write mode, the third data write unit 212A transfers write data to the corresponding memory cell.

The semiconductor memory apparatus 2 configured in such a manner commonly controls the access to the column areas of the first and second memory banks through the common column selection control unit. Therefore, the chip area required for disposing the circuits can be saved.

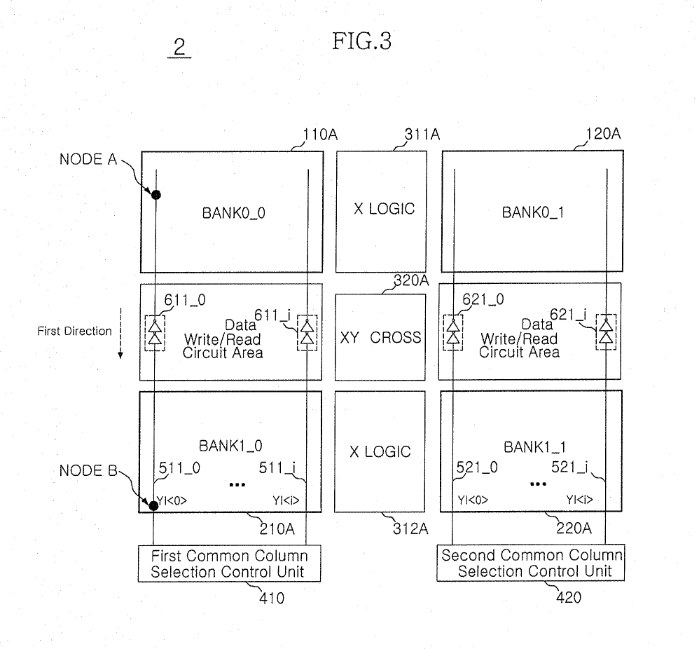

FIG. 3 is a detailed configuration diagram of the semiconductor memory apparatus 2 of FIG. 2.

Referring to FIG. 3, the semiconductor memory apparatus 2 includes the first memory banks BANK0_0 and BANK0_1 110A and 120A, the second memory banks BANK1_0 and BANK1_1 210A and 220A, the first and second common column selection control units 410 and 420, the common column selection signal transmission lines 511_0 to 511_{—}i and 521_0 to 521_{—}i, and column selection signal repeaters 611_0 to 611_{—}i and 621_0 to 621_{—}i.

For reference, the first memory banks BANK0_0 and BANK0_1 110A and 120A are divided into first and second sub banks 110A and 120A, and the second memory banks BANK1_0 and BANK1_1 210A and 220A are divided into third and fourth sub banks 210A and 220A. As such, the memory banks which are each selectively activated by a bank address signal may be arranged so as to be physically divided into the plurality of sub banks.

The first memory bank BANK0_0 and BANK0_1 110A and 120A and the second memory banks BANK1_0 and BANK1_1 210A and 220A are disposed at a predetermined distance from each other in the first direction.

The first common column selection control unit 410 is disposed at an outside region of the first sub bank 110A of the first memory banks and the third sub bank 210A of the second memory banks in the first direction. The second common column selection control unit 420 is disposed at an outside region of the second sub bank 120A of the first memory banks and the fourth sub bank 220A of the second memory banks in the first direction.

The common column selection signal transmission lines 511_0 to 511_{—}i and 521_0 to 521_{—}i are configured to transfer column selection signals YI<0> to YI<i> for controlling data access to the corresponding memory cell in the first and second memory banks. The column selection signals YI<0> to YI<i> are signals generated by the first and second common column selection control units 410 and 420.

The column selection signal repeaters 611_0 to 611_{—}i and 621_0 to 621_{—}i are inserted in the common column selection signal transmission lines 511_0 to 511_{—}i and 521_0 to 521_{—}i, respectively, and configured to transfer the corresponding column selection signals for controlling data access to the memory cells of the first memory banks. For reference, each of the column selection signal repeaters may be configured with one or more buffers or inverters.

To illustrate the technical ideas proposed in this embodiment, the following descriptions will be directed to an access operation to the first sub bank 110A of the first memory banks and the third sub bank 210A of the second memory banks. The description of an access operation to the second sub bank 120A of the first memory banks and the fourth sub bank 220A of the second memory banks will be omitted to avoid the duplicated description.

When the first sub bank 110A of the first memory banks and a specific column selection signal YI<k> are activated, data access to the corresponding memory cell in the first sub bank 110A is performed. Furthermore, when the third sub bank 210A of the second memory banks and the specific column selection signal YI<k> are activated, data access to the corresponding memory cell in the third sub bank 210A is performed. At this time, the column selection signal YI<k> is transferred through a common column selection signal transmission line. That is, the column selection signal for controlling the data access to the memory cell in the first sub bank 110A of the first memory banks and the column selection signal for controlling the data access to the memory cell in the third sub bank 210A of the second memory banks are commonly transferred through the common column selection signal transmission line.

At this time, a transmission path of the column selection signal for controlling the data access to the memory cell in the first sub bank 110A of the first memory banks is longer than that of the column selection signal for controlling the data access to the memory cell in the third sub bank 210A of the second memory banks. Therefore, when the column selection signal for controlling the data access to the memory cell in the first sub bank 110A of the first memory banks is transferred through the common column selection signal transmission line, a slew rate of the column selection signal may decrease due to a load value of the common column selection signal transmission line, such as capacitance or the like. In this embodiment, however, the column selection signal for controlling the data access to the memory cell in the first sub bank 110A of the first memory banks is transferred through a column selection signal repeater 611_{—}k, the slew rate of the column selection signal is compensated for. Therefore, although the length of the common to column selection signal transmission line is long, it is possible to reduce a variation in slew rate of the column selection signal.

Now, the column selection signals YI<0> to YI<i> generated by the first common column selection control unit 410 will be described in detail. Since the column selection signals YI<0> to is YI<i> are generated based on the same technical ideas, the first column selection signal YI<0> transferred through the first common column selection signal transmission line 511_0 will be described as a representative example.

The first column selection signal YI<0> generated by the first common column selection control unit 410 is transferred to the first sub bank 110A of the first memory banks and the third sub bank 210A of the second memory banks through the first common column selection signal transmission line 511_0. At this time, a timing difference occurs between the first column selection signal YI<0> transferred to a first node NODE A of the first common column selection signal transmission line 511_0 and the first column selection signal YI<0> transferred to a second node NODE B of the first common column selection signal transmission line 511_0. The first node NODE A may be defined as a reference at which the timing of a column selection signal for controlling data access to a memory cell in the first sub bank 110A of the first memory banks is measured, and the second node NODE B may be defined as a reference at which the timing of a column selection signal for controlling data access to a memory cell in the third sub bank 210A of the second memory banks is measured.

Since the first common column selection signal transmission line 511_0 is relatively long, the timing difference occurs between the first column selection signal YI<0> transferred to the first node NODE A and the first column selection signal YI<0> transferred to the second node NODE B. That is, the skew of the first column selection signal YI<0> between the first node NODE A and the second node NODE B is large. Furthermore, since the first column selection signal repeater 611_0 is provided to compensate for a decrease in slew rate of the first column selection signal YI<0>, the skew of the first column selection signal YI<0> further increases due to a delay of the first column selection repeater 611_0.

When generating the first column selection signal YI<0> for controlling data access to a memory cell in the third sub bank 210A of the second memory banks, the first common column selection control unit 410 according to this embodiment delays the first column selection signal YI<0> by the delay length of the first column selection signal repeater 611_0. Therefore, the timing difference between the first column selection signal YI<0> transferred to the first node NODE A and the first column selection signal YI<0> transferred to the second node NODE B, that is, the skew of the first column selection signal YI<0> decreases. Furthermore, a variation in timing of data access to the corresponding memory cells of the first and second memory banks is reduced.

When generating the first column selection signal YI<0> for controlling data access to the memory cell in the third sub bank 210A of the second memory banks, the first common column selection control unit 410 may further delay the first column selection signal YI<0> by a transmission-path delay length in addition to the delay of the first column selection signal repeater 611_0. The transmission-path delay length is defined as a delay length corresponding to a difference between a transmission path of a column selection signal for controlling data access to a memory cell in the first sub bank 110A of the first memory banks and a transmission path of a column selection signal for controlling data access to a memory cell in the third sub bank 210A of the second memory banks. In this embodiment a delay of the first common column selection signal transmission line 511_0 between the first node NODE A and the second node NODE B corresponds to the transmission-path delay length. For reference, since a large number of memory cells are arranged in the first sub bank 110A of the first memory banks and the third sub bank 210A of the second memory banks, the transmission-path length delay may not be determined based on a specific node, but an optimal delay length may be determined based on a memory bank or sub bank.

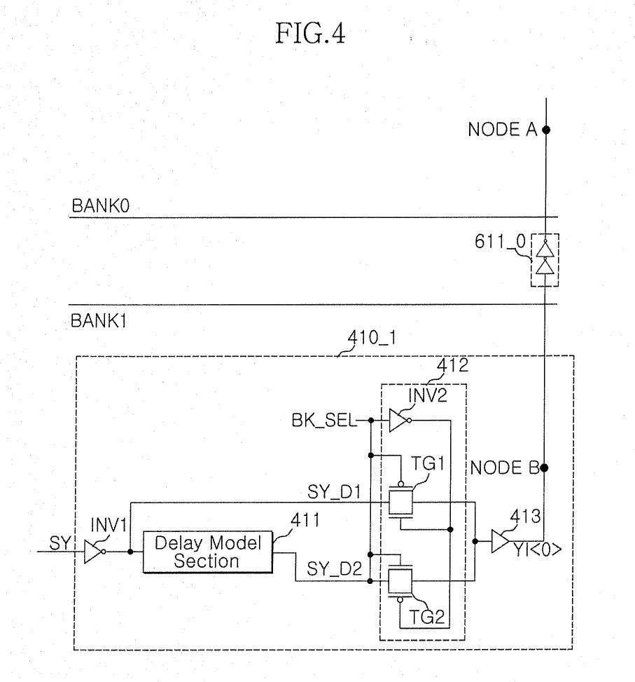

FIG. 4 is a simplified diagram of the semiconductor memory apparatus of FIG. 2 and a circuit diagram of the first common column selection control unit. While the first common column selection control unit 410 generates the column selection signals YI<0> to YI<i>, FIG. 4 illustrates only a circuit which generates the first column selection signal YI<0>. In the following descriptions, the circuit is referred to as a first common column selection control unit 410_1.

Referring to FIG. 4, the first common column selection control unit 410_1 includes a delay model section 411, a selection section 412, and a drive section 413. Here, a column enable signal

SY is inputted into a first inverter INV1, but the first inverter INV1 may also be omitted depending on the specific implementation. The delay model section 411 is configured to delay a first delayed signal SY_D1 outputted from the first inverter INV1 by a model delay length of the first column selection signal repeater 611_0, and output the delayed signal as a second delayed signal SY_D2. The selection section 412 is configured to selectively output the first delayed signal SY_D1 or the second delayed signal SY_D2 in response to a bank selection signal BK_SEL. The drive section 413 is configured to drive the signal outputted from the selection section 412 to the first common column selection signal transmission line.

Therefore, the timing of the first column selection signal YI<0> of the first node NODE A when the first memory banks are activated is substantially identical to that of the first column selection signal YI<0> of the second node NODE B when the second memory banks are activated.

In the semiconductor memory apparatus 2 according to the first embodiment, the description has been focused on the example in which only the delay of the column selection signal repeater is reflected when the column selection signal is generated. In a semiconductor memory apparatus having no column selection signal repeater, however, when a column selection signal is generated, a model delay length of a common column selection signal transmission line may be reflected to reduce the skew of the column selection signal.

Such a semiconductor memory apparatus includes a plurality of memory banks disposed at a predetermined distance from each other in a first direction, a common column selection control unit disposed at an outside region of the memory banks in the first direction and configured to commonly control access to column areas of the memory banks, and a common column selection signal transmission line configured to transfer a column selection signal for controlling data access to the corresponding memory cells of the memory banks. At this time, the common column selection control unit generates a column selection signal of which the delay is adjusted based on the length of a transmission path of the column selection signal.

The common column selection control unit includes a delay model section configured to delay a column enable signal by a model delay length of the transmission path of the column selection signal, a selection section configured to selectively output the column enable signal or the delayed signal outputted from the delay model section in response to a bank selection signal, and a drive section configured to drive the signal outputted from the selection section to the common column selection signal transmission line.

Meanwhile, the model delay length of the delay model section may be controlled in response to a bank address signal. For example, when it is assumed that first to fourth memory banks are disposed at a predetermined distance from each other in the first direction, the model delay length may be determined based on the length of a transmission path of a column selection signal depending on the disposed locations of the memory banks.

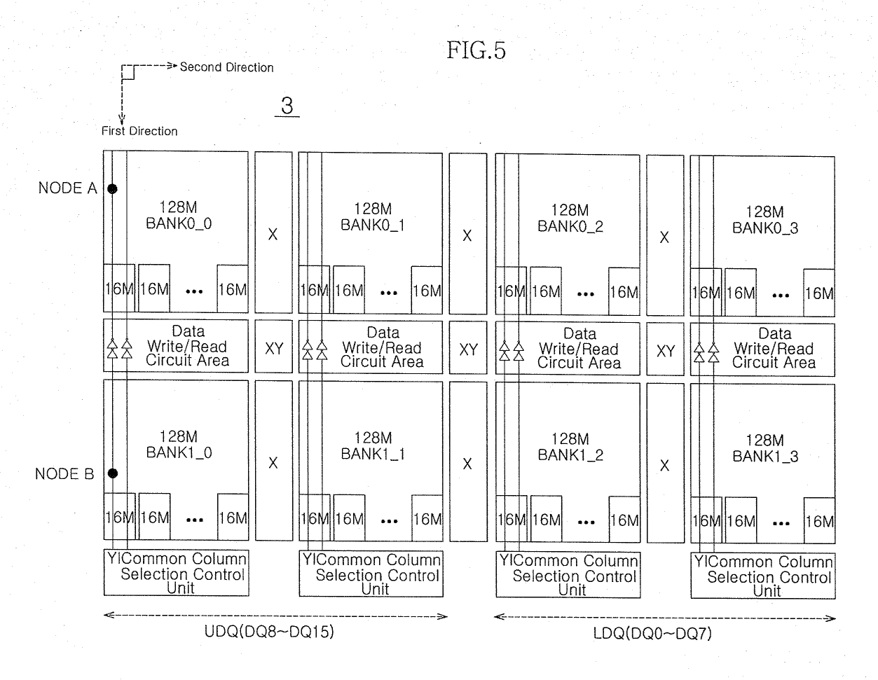

FIG. 5 illustrates an internal structure of a semiconductor memory apparatus according to a second embodiment.

Referring to FIG. 5, the semiconductor memory apparatus 3 according to the second embodiment includes first memory banks BANK0_0 to BANK0_3, second memory banks BANK1_0 to BANK1_3, common column selection control units, and so on. That is, the semiconductor memory apparatus 3 according to the second embodiment is implemented by reflecting the technical ideas applied to the semiconductor memory apparatus 2 according to the first embodiment. The first memory banks BANK0_0 to BANK0_3 and the second memory banks BANK1_0 to BANK1_3, respectively, are divided into four sub banks.

The first memory banks BANK0_0 to BANK0_3 and the second memory banks BANK1_0 to BANK1_3 are disposed at a predetermined distance respectively in a first direction. The plurality of sub banks composing the first memory bank BANK0_0 to BANK0_3 are disposed at a predetermined distance respectively in a second direction, and the plurality of sub banks composing the second memory bank BANK1_0 to BANK1_3 are also disposed at a predetermined distance respectively in the second direction.

The semiconductor memory apparatus 3 according to the second embodiment includes pads which are divided into a first data input/output pad group UDQ and a second data input/output pad group LDQ. Such an arrangement of the pads helps to obtain distributed global transmission lines, which has an advantage in terms of the chip area.

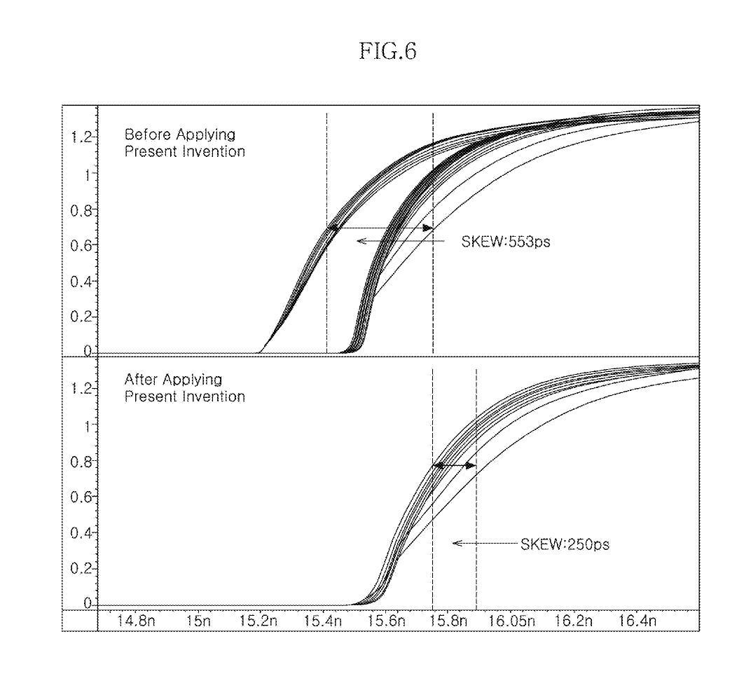

FIG. 6 illustrates a simulation result of the semiconductor memory apparatus according to the embodiments.

Referring to FIG. 6, the skew of a column selection signal before the present invention is applied may be compared with that after the present invention is applied. The skew of the column selection signal before the present invention is applied is 553 Ps, but the skew of the column selection signal after the present invention is applied is 250 ps, which means the skew decreased to almost the half.

In the semiconductor memory apparatus according to the embodiments, when a column selection signal is transferred to the plurality of memory banks through a common column selection signal transmission line, it is possible to reduce the skew of the column selection signal, even though the length of the common column selection signal transmission line is long. Furthermore, it is possible to compensate for the skew which occurs due to the delay of the column selection signal repeater inserted in the common column selection signal transmission line. Therefore, a variation in timing of data access to the corresponding memory cells of the plurality of memory banks decreases.

While certain embodiments have been described above, it will be understood to those skilled in the art that the embodiments described are by way of example only. Accordingly, the apparatus described herein should not be limited based on the described embodiments. Rather, the apparatus described herein should only be limited in light of the claims that follow when taken in conjunction with the above description and accompanying drawings.

What is claimed is:

1. A semiconductor memory apparatus comprising:
plurality of memory banks disposed at a predetermined distance from each other in a first direction;
a common column selection control unit disposed at an outside region of the plurality of memory banks in the first direction, and configured to commonly control access to column areas of the plurality memory banks; and
to a common column selection signal transmission line configured to transfer a column selection signal for controlling data access to corresponding memory cells of the plurality of memory banks,
wherein the common column selection control unit generates the column selection signal, and a delay length of the column selection signal is adjusted based on a length of a transmission path of the column selection signal.

2. The semiconductor memory apparatus of claim 1,
wherein the common column selection control unit comprises:
a delay model section configured to delay a column enable signal by a model delay length of the transmission path of the column selection signal;
a selection section configured to selectively output one of the column enable signal and the delayed column enable signal outputted from the delay model section in response to a bank selection signal as a selection section signal; and
a drive section configured to drive the selection section signal outputted from the selection section to the common column selection signal transmission line,
wherein the model delay length of the delay model section is adjusted in response to a bank address signal.

3. The semiconductor memory apparatus of claim 1,
wherein the column selection signal is activated in response to a column address signal.

4. The semiconductor memory apparatus of claim 1,
wherein the plurality of memory banks are selectively activated in response to a bank address signal.

5. The semiconductor memory apparatus of claim 1,
wherein the column selection signal controls data access to a memory cell in an activated memory bank among the plurality of memory banks.

6. A semiconductor memory apparatus comprising:
first and second memory banks disposed at a predetermined distance in a first direction;
a common column selection control unit disposed at an outside region of the first and second memory banks in the first direction, and configured to commonly control access to column areas of the first and second memory banks;
a common column selection signal transmission line configured to transfer a column selection signal for controlling data access to corresponding memory cells of the first and second memory banks, the column selection signal being generated by the common column selection control unit; and
a column selection signal repeater inserted in the common column selection signal transmission line, and configured to transfer the corresponding column selection signal for controlling data access to the memory cell in the first memory bank,
wherein a transmission path of the column selection signal for controlling data access to the memory cell in the first memory bank is longer than that of the column selection signal for controlling data access to the memory cell in the second memory bank, and
when generating the column selection signal for controlling data access to the memory cell in the second memory bank, the common column selection control unit delays the column selection signal based on a delay length of the column selection signal repeater.

7. The semiconductor memory apparatus of claim 6,
wherein when generating the column selection signal for controlling data access to the memory cell in the second memory bank, the common column selection control unit further delays the column selection signal by a transmission-path delay length in addition to the delay length of the column selection signal repeater, and
the transmission-path delay length corresponds to a difference between the transmission path of the column selection signal for controlling data access to the memory cell in the first memory bank and the transmission path of the column selection signal for controlling data access to the memory cell in the second memory bank.

8. The semiconductor memory apparatus of claim 6,
wherein the common column selection control unit comprises:
a delay model section configured to delay a column enable signal by a model delay length of the column selection signal repeater;
a selection section configured to selectively output one of the column enable signal and the delayed signal outputted from the delay model section in response to a bank selection signal as a selection section signal; and
a drive section configured to drive the selection section signal outputted from the selection section to the common column selection signal transmission line.

9. The semiconductor memory apparatus of claim 6,
wherein the column selection signal is activated in response to a column address signal.

10. The semiconductor memory apparatus of claim 6,
wherein the first and second memory banks are selectively activated in response to a bank address signal.

11. The semiconductor memory apparatus of claim 6,
wherein the column selection signal controls data access to a memory cell in an activated memory bank of the first and second memory banks.
